(19) United States
(12) Patent Application Publication
(10) Pub. No.: US 2023/0069057 A1
(43) Pub. Date: Mar. 2, 2023

(54) Growth Device and Method for Low-Stress Crystals

(71) Applicant: THE 13TH RESEARCH INSTITUTE OF CHINA ELECTRONICS TECHNOLOGY GROUP CORPORATION, Shijiazhuang, Hebei (CN)

(72) Inventors: Yanlei SHI, Shijiazhuang, Hebei (CN); Niefeng SUN, Shijiazhuang, Hebei (CN); Shujie WANG, Shijiazhuang, Hebei (CN); Lijie FU, Shijiazhuang, Hebei (CN); Huimin SHAO, Shijiazhuang, Hebei (CN); Hongfei ZHAO, Shijiazhuang, Hebei (CN); Yaqi LI, Shijiazhuang, Hebei (CN); Huisheng LIU, Shijiazhuang, Hebei (CN); Tongnian SUN, Shijiazhuang, Hebei (CN); Yong KANG, Shijiazhuang, Hebei (CN); Xiaodan ZHANG, Shijiazhuang, Hebei (CN); Xin ZHANG, Shijiazhuang, Hebei (CN); Jian JIANG, Shijiazhuang, Hebei (CN); Xiaolan LI, Shijiazhuang, Hebei (CN); Yang WANG, Shijiazhuang, Hebei (CN); Jing XUE, Shijiazhuang, Hebei (CN)

(21) Appl. No.: 17/797,063

(22) PCT Filed: Jul. 5, 2021
(86) PCT No.: PCT/CN2021/104412

§ 371 Date: Aug. 2, 2022

(30) Foreign Application Priority Data
Feb. 3, 2021 (CN) 202110145424.7
Feb. 3, 2021 (CN) 202120299367.3

(51) Int. Cl. C30B 15/00

(52) U.S. Cl. CPC C30B 15/00

(57) ABSTRACT

A growth device and method for low-stress crystals are provided, which relate to the field of preparation of crystals, in particular to a device and method for preparing low-stress and low-defect crystals by using a pulling method. The growth device includes a furnace body; a crucible and a heating and insulation system which are arranged at a bottom of the furnace body; a crystal pulling mechanism, and a quartz observation window; the device further includes a liftable heating mantle mechanism including a heating mantle body, a heating mantle supporting component, a heating wire arranged around the heating mantle body, and a heating mantle lifting mechanism. The method includes: after crystals are pulled out of a melt, covering the crystals with a liftable heating mantle mechanism. By the use of the present invention, a temperature gradient inside the crystals in a crystal growth process and in a cooling process after the crystals are pulled can be reduced, thereby reducing the crystal stress, reducing defects, and avoiding the crystals from being cracked; and at the same time, the temperature gradient in the melt is maintained, thereby guaranteeing a stable crystal growth process and ensuring the yield of the crystals.

### TECHNICAL FIELD

The present invention relates to the field of preparation of crystals, in particular to a device and method for preparing low-stress, low-defect crystals by a pulling method.

### BACKGROUND ART

A pulling method is a method for growing crystals from a melt. It is a common growth method for semiconductor crystals, optical crystals, etc. This method has the characteristics of high yield, high growth rate, easy observation, and the like.

The pulling method is a growth method usually using a single heater. In the pulling method, since crystals are pulled out of a melt, especially when the crystals are pulled to a higher position, partial crystals that are pulled out first will be cooled to a lower temperature due to a lower temperature of a surrounding atmosphere. A temperature at a crystal growth solid-liquid interface has been maintained near a melting point of a crystal. Therefore, assuming that the longitudinal temperature distribution in a crystal is linear, the gradient in the crystal is approximately equal to (T(interface)-T(surface))/L, where L is a distance from the crystal growth solid-liquid interface to a surface of crystal; T(surface) is a temperature of the surface of the crystal; and T(interface) is the temperature at the crystal growth solid-liquid interface (about the temperature of the melting point of a crystal). In a steady-state growth process, the T(interface) is approximately equal to the temperature of the melting point of the crystal, which is approximately a fixed value. A main way to reduce the temperature gradient of the crystal is to increase the temperature T(surface) of the surface of the crystal. It is a common method to perform heat insulation on and heat the pulled crystal to increase the temperature gradient of the surface of the crystal.

At present, a mainstream method is to add a heat insulation cover and a post heater above a crucible and the crystal. For example, Chinese patent application No. 201810509188.0 discloses a growth device of CeAlO3 crystals by a pulling method, and a control method thereof. The technical solution is setting two groups of fixed heating mechanisms to heat the crucible and the pulled crystals respectively. The heater and an upper cover the entire melt. However, although this method plays a heat insulation role for the crystal to a certain extent, it has a large defect in practical applications. First, the overall coverage for a crucible body by the heater and the upper cover reduces the temperature gradient of the melt, which causes that a crystal growth process easily becomes unstable, and twin crystals and even polycrystallization in the crystals appear.

Especially in an early stage (seeding and shouldering stages) of the growth of the crystal, the crystal is in a center region of the melt that has a low temperature gradient, will grow unstably, and is prone to poly-crystallization. Moreover, when this method is used for growing a compound crystal containing a volatile element (such as indium phosphide, gallium arsenide, gallium phosphide, indium arsenide, indium antimonide, gallium antimonide, and phosphorus germanium zinc), the post heater heats the crystal, which will cause dissociation of the crystal, that is, cause the volatile element to be volatilized into the atmosphere. Severe dissociation of the crystal can make the crystal useless. Therefore, using this thermal field to grow the compound crystal containing the volatile element limits the power of the post heater.

Chinese patent application No. 200910112711.7 discloses a method and device for growing large-size yttrium sodium tungstate crystals by two-stage heating and pulling method. Two groups of fixed heating mechanisms are also configured to heat the crucible and a pulled crystal respectively. However, by this device, the part over the crystal is open, so that greater heat dissipation will be caused, the heat insulation effect on the crystal is poor, and the effect of reducing stress is not obvious. Especially for a crystal containing a volatile element, a heated crystal will be greatly dissociated in a relatively open environment. For some materials, a growth environment of which has a higher pressure, a high-pressure gas flow will have a strong heat dissipation effect on unsealed crystals, thereby lowering the heating effect of the post heater.

Chinese patent application No. 201910631648.1 discloses a coil-liftable temperature field structure and single crystal growth method suitable for a pulling method. The adopted technical solution is to arrange a post heating cylinder above a crucible, and move a heating coil to heat the crucible and the post heating cylinder respectively. By this device, the external moving coil is used, which can simultaneously heat the crucible and the post heating cylinder. There is power interference between them, and the control accuracy is low. Crystal growth has an extremely high requirement for the stability of a temperature in a crucible. The movement of a coil that heats the crucible will have a greater impact on a thermal field. Moreover, a heating cylinder is induced at the same time to divide the power of the coil, so that it is extremely easy to make the temperature gradient of the melt fluctuate in a large range, causing a failure in crystal growth. A heat insulation cylinder is relatively far from the crystal, and the post heating cylinder plays a heating role for the entire environment, which will reduce both the temperature gradient of the entire environment and the temperature gradient of the melt, and will also cause the crystal growth to be less stable. In addition, the coil device heats both the melt and the crystal in the cooling process at the end of the crystal growth, but has poor heat insulation and heating effect on the crystal during the crystal growth. Defects such as stress and dislocation caused by a temperature difference between upper and lower ends of the crystals in the crystal growth process cannot be obviously improved.

### SUMMARY OF THE INVENTION

The present invention aims to solve the problems in the prior art.

To this end, the present invention is implemented by adopting the following technical means: A growth device for low-stress crystals includes a furnace body; a crucible and a heating and insulation system which are arranged at a bottom of the furnace body; a crystal pulling mechanism directly facing a center of the crucible; and a quartz observation window arranged on a side surface of the furnace body; the heating and insulation system includes a crucible, a heater, a crucible rod, and a heat insulation sleeve; the crystal pulling mechanism includes a seed rod and a seed chuck; the critical point lies in the fact that the device further includes a liftable heating mantle mechanism; the liftable heating mantle mechanism includes a heating mantle body, a heating mantle supporting component, a heating wire arranged around the heating mantle body, and a heating mantle lifting mechanism; and a thermocouple is arranged inside the heating mantle body.

Further, a top of the heating mantle body is conical, and a bottom is cylindrical; the heating mantle body is made of a transparent material; and an outer diameter of the cylindrical part is less than an inner diameter of the crucible.

Further, the seed rod passes through the heating mantle body; and the heating mantle lifting mechanism drives the liftable heating mantle mechanism to move up and down along the seed rod. Further, a gas source box is further arranged inside the liftable heating mantle mechanism.

By the adoption of the above device, in a crystal growth stage, the heating mantle is lowered to cover crystals being growing, and a consistent temperature field is formed around the crystals. Compared with the traditional two-stage temperature field, this consistent temperature field has the following characteristic: different coverage regions.

In principle, a greater temperature gradient of a melt indicates higher stability of crystal growth, so it is hoped to increase the temperature gradient of the melt to ensure steady crystal crystallization. A greater temperature gradient in the crystals indicates higher heat stress inside the crystals, so it is hoped that the temperature gradient in the crystals is small. A traditional two-stage temperature field often covers the entire crucible body, thus reducing both the temperature gradient of the crystals and the temperature gradient of the melt. Although a certain effect of reducing the stress can be achieved, the crystal growth process is prone to instability, and twin crystals and even polycrystallization in the crystals appear. In the present invention, the heating mantle body matched with the diameter of the crystals is used to keep the temperature of the crystals, without covering the melt. Therefore, the temperature gradient in the melt will not be significantly reduced, and the stable crystal growth can be ensured.

The time periods for coverage are different.

In the seeding and shouldering stages, the crystals are in the center of the melt, and the radial temperature gradient of a surface of the melt in a center region of the crucible is small. Therefore, the crystals with smaller volumes are more prone to instability in the seeding and shouldering processes, resulting in polycrystallization. A traditional non-movable two-stage thermal field covers the crucible during the whole process, so that the temperature gradient of the melt is small, which easily leads to polycrystallization in the seeding and shouldering processes.

Based on the above growth device for the low-stress crystals, the present invention further provides a growth method for low-stress crystals, including the following step: after crystals are pulled out of a melt, covering the crystals with a liftable heating mantle mechanism.

By the use of the above-mentioned device and method, in the crystal growth stage and after the crystals are pulled out of the melt, the crystals can be covered with the liftable heating mantle mechanism to form the relatively consistent temperature field around the crystals, thus reducing the temperature gradient inside the crystals in the crystal growth process and in the cooling process after the crystals are pulled, thereby reducing the crystal stress, reducing defects, and avoiding the crystals from being cracked; and at the same time, maintaining the temperature gradient in the melt, thereby guaranteeing a stable crystal growth process and ensuring the yield of the crystals.

### BRIEF DESCRIPTION OF THE DRAWINGS

FIG. 1 is a schematic structural diagram of the present invention;

FIG. 2 is a working state diagram;

FIG. 3 is another working state diagram;

FIG. 4 is an illustration of a depth marking line on a heating mantle; and

FIG. 5 is an illustration of a depth marking line on another heating mantle.

seed 1, seed chuck 2, seed rod 3, crystal 4, covering agent 5, melt 6, heater 7, heating mantle 8, heating mantle supporting component 9, heating mantle lifting mechanism 10, quartz observation window 11, crucible rod 12, heat insulation sleeve 13, heating wire 14, gas source box fixing pin 15, gas source material 16, gas source box 17, crucible 18, furnace body 19, heating wire wrap 20, and thermocouple 21.

### DETAILED DESCRIPTION OF THE INVENTION

The present invention will be further described below in conjunction with the drawings.

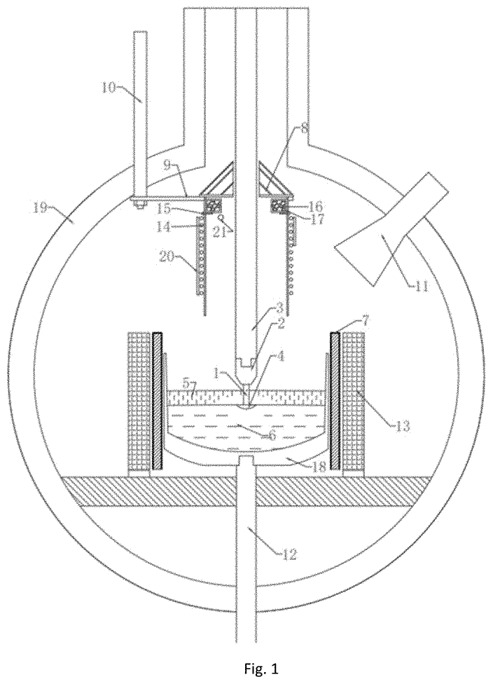

A growth device for low-stress crystals, referring to FIG. 1, includes a furnace body 19; a crucible 18 and a heating and insulation system which are arranged at a bottom of the furnace body 19; a crystal pulling mechanism directly facing the center of the crucible; and a quartz observation window 11 arranged on a side surface of the furnace body 19.

The heating and insulation system includes a heater 7 arranged around the crucible 18, a crucible rod 12 which supports the crucible 18 from the bottom, and a heat insulation sleeve 13 outside the heater 7.

The crystal pulling mechanism includes a seed rod 3 and a seed chuck 2.

The device further includes a liftable heating mantle mechanism, including a heating mantle body 8, a heating mantle supporting component 9, a heating wire 14 arranged around the heating mantle body 8, and a heating mantle lifting mechanism 10. The heating mantle lifting mechanism 10 completes lifting of the heating mantle body 8 through the heating mantle supporting component 9. A thermocouple 21 is arranged inside the heating mantle body 8 to acquire its internal temperature.

A top of the heating mantle body 8 is conical, and a bottom is cylindrical. The heating mantle body is made of a transparent material such as quartz, glass or sapphire. The heat of the heating wire 14 can be radiated into the heating mantle body to heat crystals. A peripheral part of the heating wire 14 is covered with a heating wire wrap 20, so that after the heating mantle body 8 is lowered, the growth of the crystals can still be observed through the mantle body.

An inner diameter of the heating mantle body 8 is 5-10 mm greater than the diameter of a crystal to be drawn, and an outer diameter of its cylindrical part is less than an inner diameter of the crucible 18, so that there is no overall coverage effect on the crucible 18.

The top of the heating mantle body 8 is of a multi-layer hollow structure to form a plurality of cavities, which has a certain heat insulation effect.

The heating mantle mechanism is attached to the seed rod 3; the seed rod 3 passes through the heating mantle body 8; and the heating mantle lifting mechanism 10 drives the liftable heating mantle mechanism to move up and down along the seed rod 3.

The top of the heating mantle body 8 is clung to the seed rod 3, and there is a gap between the heating mantle body 8 and the seed rod 3. The gap is not more than 2 mm for communicating the interior of the heating mantle body 8 to the interior of the furnace body 19, so that the pressure is kept to be basically the same.

A gas source box 17 is also provided inside the liftable heating mantle mechanism, and the gas source box 17 is positioned on at an inner upper end of the heating mantle body 8 by using a gas source box fixing pin 15. There are no less than four gas source box fixing pins 15 along a radial direction of the heating mantle body 8 to ensure that the position of the gas source box is stable. In order to avoid the heating wire 14 from being immersed in a covering agent 5 and a melt 6, no heating wire is provided at the bottom of the heating mantle body 8. The heating wire 14 is disposed at a start position upward from the bottom of the heating mantle body 8, which is ⅙ greater than the length of the heating mantle body 8.

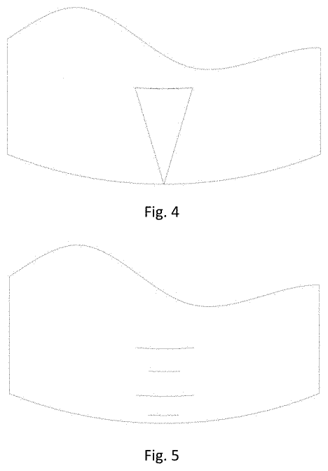

In order to facilitate the observation, a depth marking line is set at a periphery of the heating mantle body 8 from the bottom. The depth marking line adopts an inverted triangle, as shown in FIG. 4, intuitively representing a depth of the heating mantle body 8 immersed into the covering agent 5. Spaced lines can be used to represent the depth, as shown in FIG. 5.

The observation window 11 is made of a transparent material such as quartz, glass or sapphire, and is used for observing the growth of the crystals. After the liftable heating mantle mechanism is lowered, the quartz observation window 11 is aligned with the set marking line.

The heating mantle lifting mechanism 10 can finely adjust the heating mantle body 8 up and down to ensure that the lower part of the heating mantle body 8 is in continuous contact with the covering agent 5 when the liquid level of the covering agent 5 drops.

Working process: A gas source material 16 is a volatile element material in a compound crystal. Phosphorus is used as the gas source material 16 for growing indium phosphide crystals, gallium phosphide crystals, etc.; and arsenic is used as the gas source material 16 for growing gallium arsenide crystals. The gas source material 16 is placed in the gas source box 17 and put into the inner heating mantle body 8. The covering agent 5 uses boron oxide.

Step I: A raw material and the covering agent are placed in the crucible 18; and the heater 7 is turned on for a period of time until the raw material and the covering agent 5 in the crucible 18 are melted, where the covering agent 5 is covered on the raw material melt 6 since its density is less than that of the raw material.

Step II: A seed 1 is arranged on the seed chuck 2, and the crystal pulling mechanism is lowered until the seed 1 is in contact with a surface of the melt 6. If the temperature of the melt is suitable for crystal growth, after the contact, the position of the seed 1 that is in contact with the melt 6 will gradually grow to become a crystal 4.

Step III: The growth of the crystal 4 at the position of the seed 1 that is in contact with the melt 6 is observed through the quartz observation window 11. The power of the heater 7 is adjusted according to the expansion/shrinkage of the crystal 4, so that the crystal 4 grows gradually. In the process of gradual crystal growth, the pulling speed of the pulling mechanism is gradually changed.

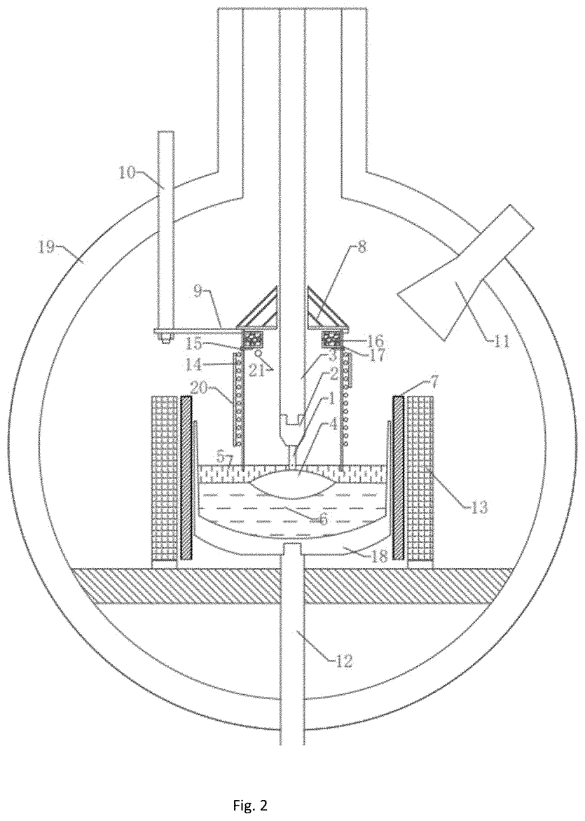

Step IV: When the crystal 4 grows to a desired diameter, a power supply of the heating wire 14 is turned on, and the heating mantle mechanism is lowered, so that the bottom of the heating mantle body 8 is in contact with the covering agent 5. The peripheral part of the heating wire 14 covers the heating wire wrap 20, and a position close to the observation window 11 is not covered to expose the observation window, as shown in FIG. 2.

The above “desired diameter” is about a standard wafer size +5 mm. For example, if a crystal with a target diameter of 2 inches is prepared, the desired diameter is 55.8 mm; if a crystal with a target diameter of 3 inches is prepared, the desired diameter is 81.2 mm; if a crystal with a target diameter of 4 inches is prepared, the desired diameter is 105 mm; and if a crystal with a target diameter of 6 inches is prepared, the desired diameter is 155 mm.

Step V: The heating power of the heating wire 14 is gradually increased, so that the environment temperature in the heating mantle is significantly increased, and a temperature range is determined according to a gas source element. If the gas source element is phosphorus, the temperature is raised to 500-600° C., and the gas source starts to volatilize gas, so as to ensure an environment partial pressure of the gas source element in the heating mantle body 8. Heating is continued to maintain the temperature in the heating mantle body 8. The temperature is determined according to the thermocouple 21.

There is a small gap between the heating mantle body 8 and the seed rod 3. Gas pressures inside and outside the heating mantle body 8 are the same, but the partial pressure of the gas source element in the heating mantle body 8 is relatively high, which can inhibit the dissociation of the crystal.

There is an inert gas, such as nitrogen and argon, inside the furnace body 19, but the inert gas has a limited effect on the dissociation of the crystal, and the partial pressure of the corresponding gas element can inhibit the dissociation. Therefore, the gas source material 16 is used to provide the partial pressure of the element around the crystal to limit the escape of the element from a surface of the crystal.

Step VI: With the gradual growth and pulling of the crystal 4, the liquid levels of the melt 6 and the covering agent 5 gradually decline. Therefore, the heating mantle mechanism also needs to be gradually lowered with the decline of the liquid level, observed through the observation window 11; the position is adjusted according to the marking line to ensure the contact between the heating mantle body 8 and the boron oxide that is the covering agent 5, and to avoid the heating wire 14 from being immersed in the covering agent 5.

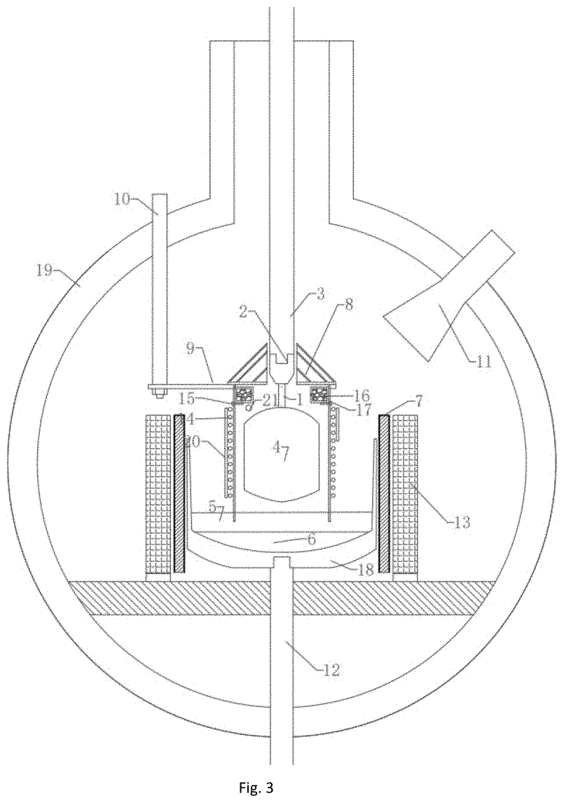

Step VII: The crystal 4 is pulled to a position that satisfies the weight; the crystal pulling mechanism and the liftable heating mantle mechanism are quickly pulled to pull the crystal 4 out of the melt 6 and the boron oxide 5, as shown in FIG. 3.

Step VIII: The heater 7 and the heating wire 14 are cooled synchronously. A cooling program is configured for the heater 7 to cool the heater to room temperature in 5-20 h. The program is enabled to cool the heating wire 14 to the room temperature in 5-20 h.

One cooling program is configured for both the heater 7 and the heating wire 14 to simultaneously reduce the temperature around the crystal slowly and reduce the temperature gradient inside the crystal.

During the cooling after the crystal growth is completed, since the lower part of the heating mantle body 8 is open, the melt below and a polycrystalline material after the solidification of the melt will achieve an effect of heating or heat insulation below the crystal. The heater and the heating wire are synergistically cooled to reduce the temperature gradient of the crystal.

Step IX: The furnace is disassembled, and the crystal is removed.

It should be noted that the gas source material 16 is subjected to a dual baking effect of the heating wire and the pulled crystal at the same time. The gasification temperature of the gas source material 16 is related to a partial pressure of a gas element nearby. If the partial pressure of the gas element is low, the gasification point of the gas source material is lowered, and it is easier to volatilize a gas element to increase the partial pressure of the element. The presence of a sufficient amount of gas source material provides a continuous flow of a gas element to the partial pressure of the element inside the mantle body. Therefore, the loading amount of the gas source material should be matched with the gasification rate, growth cycle of the crystal, and other factors.

The present invention is especially suitable for the growth of a compound crystal containing a volatile element. The gas source box 17 in the heating mantle body of the device can continuously supply the volatile element to ensure the partial pressure of the element in the atmosphere, thereby avoiding the dissociation of the compound.

When a traditional pulling method (with an upper heater or a heat insulation mantle) is used to grow a compound crystal containing a volatile element, it is necessary to increase the temperature of the crystal and reduce the temperature gradient to reduce defects; and at the same time, it should be considered that the crystal will be continuously dissociated in a high-temperature state, and will be then useless. Therefore, the temperature gradient of the crystal cannot be effectively reduced in the actual process for the thermal insulation and heating of compound crystals containing volatile elements. When the heating mantle body mechanism in the device is working, it is in contact with the covering agent, and the surrounding environment of the crystal is in a semi-closed state, and a gas source box is provided, and the volatile elements maintain a high partial pressure in the cover continuously. Increase the temperature inside the shield by a large amount without worrying about compound dissociation. In an actual process, the temperature around an indium phosphide crystal is increased to 880° C. for continuous 10 h, and the surface of the crystal is not significantly dissociated.

The device of the present invention is used to grow a 4-inch indium phosphide single crystal. The temperature gradient in the crystal is reduced from 70° C./cm in the traditional pulling method to 10° C./cm, and the dislocation density of P-type and N-type indium phosphide crystals is reduced from 20000-50000 cm−3 reduced to 300-3000 cm−3. The dislocation density of an SI-type indium phosphide crystal is reduced from 50000-100000 cm−3 to 2000-10000 cm−3.

The device and method of the present invention are used to grow crystals. The heating mantle mechanism is lowered after the crystals are seeded and shouldered. The yield of the crystal in this method is significantly greater than that of the Czochralski method with an ordinary, unmovable heat mantle. For example, the yield of the 4-inch indium phosphide crystal in the method of the present invention is about 60%, while the yield of such crystal in the Czochralski method with an ordinary, unmovable heat mantle is only about 30%.

1. A growth device for low-stress crystals, characterized by comprising a furnace body (19); a crucible (18) and a heating and insulation system which are arranged at a bottom of the furnace body (19); a crystal pulling mechanism directly facing a center of the crucible (18); and a quartz observation window (11) arranged on a side surface of the furnace body (19), wherein the heating and insulation system comprises a heater (7), a crucible rod (12), and a heat insulation sleeve (13); the crystal pulling mechanism comprises a seed rod (3) and a seed chuck (2); the device further comprises a liftable heating mantle mechanism; the liftable heating mantle mechanism comprises a heating mantle body (8), a heating mantle supporting component (9), a heating wire (14) arranged around the heating mantle body (8), and a heating mantle lifting mechanism (10); and a thermocouple (21) is arranged inside the heating mantle body (8).

2. The growth device for the low-stress crystals according to claim 1, characterized in that a top of the heating mantle body (8) is a conical multi-layer hollow structure, and a bottom is cylindrical; the heating mantle body is made of a transparent material; and an outer diameter of the cylindrical part is less than an inner diameter of the crucible (18).

3. The growth device for the low-stress crystals according to claim 1 or 2, characterized in that the seed rod (3) passes through the heating mantle body (8); and the heating mantle lifting mechanism (10) drives the liftable heating mantle mechanism to move up and down along the seed rod (3); and a gap reserved between the seed rod (3) and the top of the heating mantle body (8) does not exceed 2 mm.

4. The growth device for the low-stress crystals according to claim 1, characterized in that a gas source box (17) is further arranged inside the liftable heating mantle mechanism; and the gas source box (17) is positioned at an inner upper end of the heating mantle body (8) by using a gas source box fixing pin (15).

5. The growth device for the low-stress crystals according to claim 1, characterized in that a heating wire (14) is disposed at a start position upward from the bottom of the heating mantle body (8), which is ⅙ greater than the length of the heating mantle body (8).

6. The growth device for the low-stress crystals according to claim 1, characterized in that a depth marking line is set at a periphery of the heating mantle body (8) from the bottom.

7. The growth device for the low-stress crystals according to claim 6, characterized in that after the liftable heating mantle mechanism is lowered, the quartz observation window (11) is aligned to the set marking line.

8. A growth method for low-stress crystals, which is completed on the basis of the growth device for low-stress crystals according to any one of claims 1 to 7, characterized in that the growth method comprises the following step:
after crystals are pulled out of a melt, covering the crystals with a liftable heating mantle mechanism.

9. The growth method for the low-stress crystals according to claim 8, characterized in that the growth method comprises the following steps:
A. placing a raw material and the covering agent (5) in the crucible (18); placing a gas source material (16) in the gas source box (17); and turning on the heater (7) for heating until the raw material and the covering agent (5) are melted, wherein the raw material becomes a melt (6);
B. disposing a seed (1) on a seed chuck (2), and lowing the seed rod (3) until the seed (1) is in contact with a surface of the melt (6);
C. when a crystal (4) grows to a desired diameter, turning on a power supply of a heating wire (14); and lowering the liftable crystal heating mantle to enable the bottom of the heating mantle body (8) to be in contact with the covering agent (5), wherein the desired diameter refers to a wafer size +5 mm;
D. in a growth process of the crystal (4), maintaining a temperature in the heating mantle body (8);
lowering the heating mantle mechanism with a decline in a liquid level of the covering agent (5) to keep the bottom of the heating mantle body (8) being in contact with the covering agent (5);
measuring the temperature inside the mantle through the thermocouple (21) inside the mantle; and
when the crystal (4) is to be pulled out of the covering agent (5), increasing the power of the heating wire (14) to ensure that the temperature inside the mantle reaches a gasification temperature of the gas source material (16);
E. after the growth of the crystal (4) is completed, pulling the crystal (4) to a position above the liquid level of the covering agent (5);
F. enabling a program to cool the heating wire 14 to room temperature in 5-20 h; and configuring a cooling program for the heater (7) to cool the same to the room temperature in 5-20 h;
G. disassembling the furnace, and removing the crystal (4), wherein the heating wire (14) is disposed at a start position upward from the bottom of the heating mantle body (8), which is ⅙ greater than the length of the heating mantle body (8);
in the steps C and D, the heating wire (14) is avoided form being immersed in the covering agent (5);
in the step A, the raw material is a semiconductor material for generating a wafer.

10. The growth method for the low-stress crystals according to claim 9, characterized in that the raw material is one of indium phosphide, gallium arsenide, gallium phosphide, indium arsenide, indium antimonide, gallium antimonide, and phosphorus germanium zinc; and the gas source material (16) is selected according to the raw material, and is one of phosphorus, arsenic, and antimony.
